(19) United States
(12) Patent Application Publication
(10) Pub. No.: US 2021/0396989 A1
(43) Pub. Date: Dec. 23, 2021

(54) METHODS FOR FORMING PATTERNED INSULATING LAYERS ON CONDUCTIVE LAYERS AND DEVICES MANUFACTURED USING SUCH METHODS

(71) Applicant: CORNING INCORPORATED, CORNING, NY (US)

(72) Inventor: Thomas Mikio Wynne, Santa Barbara, CA (US)

(21) Appl. No.: 17/296,913

(22) PCT Filed: Nov. 12, 2019
(86) PCT No.: PCT/US2019/060813

§ 371 Date: May 25, 2021

Related U.S. Application Data
(60) Provisional application No. 62/771,332, filed on Nov. 26, 2018.

(51) Int. Cl. G02B 26/00; G03F 7/20

(52) U.S. Cl. CPC G02B 26/005; G03F 7/2053

(57) ABSTRACT

A method for forming a patterned insulating layer on a conductive layer can include severing a mask disposed on the conductive layer using photochemical ablation along a perimeter of a central region of the mask. The central region of the mask can be removed to form an opening in the mask, whereby a remaining region of the mask surrounding the opening in the mask covers a corresponding surrounding region of the conductive layer. An insulating layer can be applied to the central region of the conductive layer and the remaining region of the mask. The remaining region of the mask can be removed from the conductive layer to remove an excess portion of the insulating layer disposed on the remaining region of the mask, whereby a remaining portion of the insulating layer corresponding to the opening in the mask defines the patterned insulating layer disposed on the conductive layer.

### CROSS-REFERENCE TO RELATED APPLICATIONS

This application claims the benefit of priority under 35 U.S.C. § 119 of U.S. Provisional Application No. 62/771,332, filed Nov. 26, 2018, the content of which is incorporated herein by reference in its entirety.

### BACKGROUND

### 1. Field

This disclosure relates to methods for forming patterned insulating layers on conductive layers and devices, such as electrowetting devices, manufactured using such methods.

### 2. Technical Background

A variety of devices, such as electrowetting based optical devices, can include patterned insulating layers deposited on conductive layers. Various methods for depositing and/or patterning the insulating layers can damage the underlying conductive layers and/or produce patterned conductive layers with poor edge quality. Damaged conductive layers and/or poor quality patterned insulating layers can impair the performance and/or reliability of the finished device.

### SUMMARY

Disclosed herein are methods for forming patterned insulating layers on conductive layers and devices, such as electrowetting devices, manufactured using such methods.

Disclosed herein is a method for forming a patterned insulating layer on a conductive layer. A mask disposed on the conductive layer is severed using photochemical ablation along a perimeter of a central region of the mask. The central region of the mask is removed to form an opening in the mask and uncover a central region of the conductive layer corresponding to the opening in the mask, whereby a remaining region of the mask surrounding the opening in the mask covers a corresponding surrounding region of the conductive layer. An insulating layer is applied to the central region of the conductive layer and the remaining region of the mask. The remaining region of the mask is removed from the conductive layer to remove an excess portion of the insulating layer disposed on the remaining region of the mask, whereby a remaining portion of the insulating layer corresponding to the opening in the mask defines the patterned insulating layer disposed on the central region of the conductive layer, and the surrounding region of the conductive layer is uncovered by the patterned insulating layer.

Disclosed herein is a method for forming a patterned insulating layer on a conductive layer. A mask is applied to the conductive layer disposed on a wafer comprising a plurality of wells. The mask is severed with a pulsed laser with an average power of at most about 75 mW and a pulse energy of at most about 0.3 μJ along a perimeter of each of a plurality of central regions of the mask, each of the plurality of central regions overlying a corresponding one of the plurality of wells. Each of the plurality of central regions of the mask is removed to form a plurality of openings in the mask and uncover a plurality of central regions of the conductive layer each disposed at least partially in a corresponding one of the plurality of wells, whereby a remaining region of the mask surrounding the plurality of openings in the mask covers a corresponding surrounding region of the conductive layer disposed outside the plurality of wells. An insulating layer is applied to each of the plurality of central regions of the conductive layer and the remaining region of the mask. The remaining region of the mask is removed from the conductive layer to remove an excess portion of the insulating layer disposed on the remaining region of the mask, whereby a remaining portion of the insulating layer corresponding to the plurality of openings in the mask defines the patterned insulating layer disposed at least partially within the plurality of wells, and the surrounding region of the conductive layer is uncovered by the patterned insulating layer.

Disclosed herein is an electrowetting device comprising a first window, a second window, and a cavity disposed between the first window and the second window. A first liquid and a second liquid are disposed within the cavity. The first liquid and the second liquid are substantially immiscible with each other, whereby a liquid interface is formed between the first liquid and the second liquid. A common electrode is in electrical communication with the first liquid. A driving electrode is disposed on a sidewall of the cavity. An insulating layer is disposed within the cavity to insulate the driving electrode from the first liquid and the second liquid. An exposed portion of the common electrode disposed within the cavity is substantially free of scratches and thermal damage.

It is to be understood that both the foregoing general description and the following detailed description are merely exemplary, and are intended to provide an overview or framework to understanding the nature and character of the claimed subject matter. The accompanying drawings are included to provide a further understanding and are incorporated in and constitute a part of this specification. The drawings illustrate one or more embodiment(s), and together with the description, serve to explain principles and operation of the various embodiments.

### BRIEF DESCRIPTION OF THE DRAWINGS

FIG. 1 is a schematic cross-sectional view of some embodiments of an electrowetting device.

FIG. 2 is a schematic front view of the electrowetting device of FIG. 1 looking through a first outer layer.

FIG. 3 is a schematic rear view of the electrowetting device of FIG. 1 looking through a second outer layer.

FIG. 4 is a flowchart illustrating some embodiments of a method for forming a patterned insulating layer on a conductive layer.

FIG. 5 is a schematic cross-sectional view of some embodiments of a mask disposed on a conductive layer.

FIG. 6 is a schematic cross-sectional view of some embodiments of a mask severed along a perimeter of a central region of the mask.

FIG. 7 is a schematic top view of some embodiments of a mask severed along a perimeter of a central region of the mask.

FIG. 8 is a close-up view of a portion of some embodiments of a gap shown in FIG. 7.

FIG. 9 is a schematic cross-sectional view of some embodiments of a mask disposed on a conductive layer with a central region of the mask removed to form an opening in the mask.

FIG. 10 is a schematic cross-sectional view of some embodiments of an insulating layer disposed on a conductive layer.

FIG. 11 is a schematic cross-sectional view of some embodiments of an insulating layer disposed on a conductive layer with an annular region of the insulating layer removed.

FIGS. 12-13 are photographs of patterned insulating layers formed on conductive layers without removing annular regions of the insulating layers prior to removing the masks.

FIG. 14 is a schematic cross-sectional view of some embodiments of an insulating layer disposed on a conductive layer with residue removed.

FIG. 15 is a schematic cross-sectional view of some embodiments of a patterned insulating layer disposed on a conductive layer following removal of a remaining region of a mask from the conductive layer.

FIG. 16 is a perspective view of some embodiments of a substrate wafer comprising a plurality of wells formed therein.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments.

Numerical values, including endpoints of ranges, can be expressed herein as approximations preceded by the term “about,” “approximately,” or the like. In such cases, other embodiments include the particular numerical values. Regardless of whether a numerical value is expressed as an approximation, two embodiments are included in this disclosure: one expressed as an approximation, and another not expressed as an approximation. It will be further understood that an endpoint of each range is significant both in relation to another endpoint, and independently of another endpoint.

In various embodiments, a method for forming a patterned insulating layer on a conductive layer comprises severing a mask disposed on the conductive layer along a perimeter of a central region of the mask. In some embodiments, the mask is severed using photochemical ablation. The mask can be severed using a laser with a sufficiently high photon energy and sufficiently low wavelength for photochemical ablation. The laser can be operated at relatively low power and/or pulse energy to avoid burning the mask and/or damaging the underlying conductive layer. For example, the mask can be severed using a pulsed laser with an average power of at most about 75 mW and a pulse energy of at most about 0.3 μJ. The central region of the mask can be removed to form an opening in the mask and uncover a central region of the conductive layer corresponding to the opening in the mask, whereby a remaining region of the mask surrounding the opening in the mask covers a corresponding surrounding region of the conductive layer. An insulating layer can be applied to the central region of the conductive layer and the remaining region of the mask. An annular region of the insulating layer overlying the perimeter of the opening in the mask can be removed. For example, the annular region of the insulating layer can be removed by laser ablation. An inner portion of the annular region can be disposed on the central region of the conductive layer, and an outer portion of the annular region can be disposed on the mask. Following removal of the annular region, an annular portion of the central region of the conductive layer can be uncovered by each of the mask and the insulating layer. The remaining region of the mask can be removed from the conductive layer to remove an excess portion of the insulating layer disposed on the remaining region of the mask, whereby a remaining portion of the insulating layer corresponding to the opening in the mask defines the patterned insulating layer disposed on the central region of the conductive layer, and the surrounding region of the conductive layer is uncovered by the patterned insulating layer.

The methods described herein can be used to manufacture a variety of devices. For example, an electrowetting device (e.g., a liquid lens) can be manufactured using the methods described herein. In various embodiments, an electrowetting device comprises a first window, a second window, and a cavity disposed between the first window and the second window. A first liquid and a second liquid can be disposed within the cavity. The first liquid and the second liquid can be substantially immiscible with each other, whereby a liquid interface is formed between the first liquid and the second liquid. A common electrode can be in electrical communication with the first liquid. A driving electrode can be disposed on a sidewall of the cavity. An insulating layer can be disposed within the cavity to insulate the driving electrode from the first liquid and the second liquid. An exposed portion of the common electrode disposed within the cavity can be substantially free of scratches and thermal damage. For example, forming the insulating layer using the methods described herein can avoid the types of scratches and thermal damage that could be caused by forming the insulating layer using conventional patterning techniques. The insulating layer can be substantially free of flaps and stringers. For example, forming the insulating layer using the methods described herein can avoid the types of flaps and stringers that could be caused by forming the insulating layer using conventional patterning techniques.

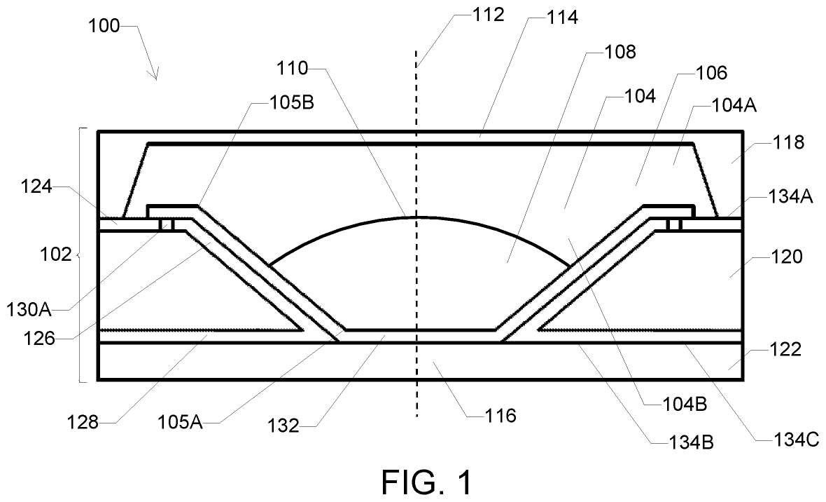

FIG. 1 is a schematic cross-sectional view of some embodiments of an electrowetting device 100. In the embodiments shown in FIG. 1, electrowetting device 100 is configured as a liquid lens. However, other embodiments are included in this disclosure. For example, in some other embodiments, the electrowetting device is configured as an optical shutter, a display element, or another suitable electrowetting based device (e.g., in which a fluid can be manipulated by exposure to an electric field).

In some embodiments, electrowetting device 100 comprises a body 102 and a cavity 104 formed in the body. A first liquid 106 and a second liquid 108 are disposed within cavity 104. In some embodiments, first liquid 106 is a polar liquid or a conducting liquid. Additionally, or alternatively, second liquid 108 is a non-polar liquid or an insulating liquid. In some embodiments, first liquid 106 and second liquid 108 are immiscible with each other, whereby a liquid interface 110 is formed between the first liquid and the second liquid. First liquid 106 and second liquid 108 can have the same or different refractive indices. For example, first liquid 106 and second liquid 108 have different refractive indices such that interface 110 forms a lens. Interface 110 with optical power can be beneficial for use as a variable focus and/or variable tilt lens (e.g., by changing the shape of the interface as described herein). Alternatively, first liquid 106 and second liquid 108 have the same or substantially the same refractive indices such that interface 110 has little or no optical power. Interface 110 with little or no optical power can be beneficial for use as an optical shutter that can be opened or closed without substantially changing the optical path of image radiation passing through electrowetting device 100. In some embodiments, first liquid 106 and second liquid 108 have substantially the same density, which can help to avoid changes in the shape of interface 110 as a result of changing the physical orientation of electrowetting device 100 (e.g., as a result of gravitational forces).

In some embodiments, cavity 104 comprises a first portion, or headspace, 104A and a second portion, or base portion, 104B. For example, second portion 104B of cavity 104 is defined by a bore in an intermediate layer of electrowetting device 100 as described herein. Additionally, or alternatively, first portion 104A of cavity 104 is defined by a recess in a first outer layer of electrowetting device 100 and/or disposed outside of the bore in the intermediate layer as described herein. In some embodiments, at least a portion of first liquid 106 is disposed in first portion 104A of cavity 104. Additionally, or alternatively, second liquid 108 is disposed within second portion 104B of cavity 104. For example, substantially all or a portion of second liquid 108 is disposed within second portion 104B of cavity 104. In some embodiments, the perimeter of interface 110 (e.g., the edge of the interface in contact with the sidewall of the cavity) is disposed within second portion 104B of cavity 104.

Interface 110 can be adjusted via electrowetting. For example, a voltage can be applied between first liquid 106 and a surface of cavity 104 (e.g., an electrode positioned near the surface of the cavity and insulated from the first liquid as described herein) to increase or decrease the wettability of the surface of the cavity with respect to the first liquid and change the shape of interface 110. In some embodiments, adjusting interface 110 changes the shape of the interface, which can change the focal length or focus of electrowetting device 100 and/or the optical transmission of the electrowetting device. A change of focal length can enable electrowetting device 100 to perform an autofocus function. Additionally, or alternatively, adjusting interface 110 tilts the interface relative to an optical axis 112 of electrowetting device 100 (e.g., to perform an optical image stabilization (OIS) function). Additionally, or alternatively, a change of optical transmission can enable electrowetting device 100 to selectively pass or block image radiation (e.g., to perform an optical shutter function). Adjusting interface 110 can be achieved without physical movement of electrowetting device 100 relative to an image sensor, a fixed lens or lens stack, a housing, or other components of a camera module in which the electrowetting device can be incorporated.

In some embodiments, body 102 of electrowetting device 100 comprises a first window 114 and a second window 116. In some of such embodiments, cavity 104 is disposed between first window 114 and second window 116. In some embodiments, body 102 comprises a plurality of layers that cooperatively form the body. For example, in the embodiments shown in FIG. 1, body 102 comprises a first outer layer 118, an intermediate layer 120, and a second outer layer 122. In some of such embodiments, intermediate layer 120 comprises a bore formed therethrough. First outer layer 118 can be bonded to one side (e.g., the object side) of intermediate layer 120. For example, first outer layer 118 is bonded to intermediate layer 120 at a bond 134A. Bond 134A can be an adhesive bond, a laser bond (e.g., a laser weld), or another suitable bond capable of maintaining first liquid 106 and second liquid 108 within cavity 104. Additionally, or alternatively, second outer layer 122 can be bonded to the other side (e.g., the image side) of intermediate layer 120. For example, second outer layer 122 is bonded to intermediate layer 120 at a bond 134B and/or a bond 134C, each of which can be configured as described herein with respect to bond 134A. In some embodiments, intermediate layer 120 is disposed between first outer layer 118 and second outer layer 122, the bore in the intermediate layer is covered on opposing sides by the first outer layer and the second outer layer, and at least a portion of cavity 104 is defined within the bore. Thus, a portion of first outer layer 118 covering cavity 104 serves as first window 114, and a portion of second outer layer 122 covering the cavity serves as second window 116.

In some embodiments, cavity 104 comprises first portion 104A and second portion 104B. For example, in the embodiments shown in FIG. 1, second portion 104B of cavity 104 is defined by the bore in intermediate layer 120, and first portion 104A of the cavity is disposed between the second portion of the cavity and first window 114. In some embodiments, first outer layer 118 comprises a recess as shown in FIG. 1, and first portion 104A of cavity 104 is disposed within the recess in the first outer layer. Thus, first portion 104A of cavity 104 is disposed outside of the bore in intermediate layer 120.

In some embodiments, cavity 104, or a portion thereof (e.g., second portion 104B of the cavity), is tapered as shown in FIG. 1 such that a cross-sectional area of the cavity decreases along optical axis 112 in a direction from the object side to the image side. For example, second portion 104B of cavity 104 comprises a narrow end 105A and a wide end 105B. The terms “narrow” and “wide” are relative terms, meaning the narrow end is narrower than the wide end. Such a tapered cavity can help to maintain alignment of interface 110 between first liquid 106 and second liquid 108 along optical axis 112. In other embodiments, the cavity is tapered such that the cross-sectional area of the cavity increases along the optical axis in the direction from the object side to the image side or non-tapered such that the cross-sectional area of the cavity remains substantially constant along the optical axis.

In some embodiments, image radiation enters electrowetting device 100 through first window 114, passes through first liquid 106, interface 110, and/or second liquid 108, and exits the electrowetting device through second window 116. In some embodiments, first outer layer 118 and/or second outer layer 122 comprise a sufficient transparency to enable passage of the image radiation. For example, first outer layer 118 and/or second outer layer 122 comprise a polymeric, glass, ceramic, or glass-ceramic material. In some embodiments, outer surfaces of first outer layer 118 and/or second outer layer 122 are substantially planar. In other embodiments, outer surfaces of the first outer layer and/or the second outer layer are curved (e.g., concave or convex). Thus, the electrowetting device comprises an integrated fixed lens. In some embodiments, intermediate layer 120 comprises a metallic, polymeric, glass, ceramic, or glass-ceramic material. Because image radiation can pass through the bore in intermediate layer 120, the intermediate layer may or may not be transparent.

Although body 102 of electrowetting device 100 is described as comprising first outer layer 118, intermediate layer 120, and second outer layer 122, other embodiments are included in this disclosure. For example, in some other embodiments, one or more of the layers is omitted. For example, the bore in the intermediate layer can be configured as a blind hole that does not extend entirely through the intermediate layer, and the second outer layer can be omitted. Although first portion 104A of cavity 104 is described herein as being disposed within the recess in first outer layer 118, other embodiments are included in this disclosure. For example, in some other embodiments, the recess is omitted, and the first portion of the cavity is disposed within the bore in the intermediate layer. Thus, the first portion of the cavity is an upper portion of the bore, and the second portion of the cavity is a lower portion of the bore. In some other embodiments, the first portion of the cavity is disposed partially within the bore in the intermediate layer and partially outside the bore.

In some embodiments, electrowetting device 100 comprises a common electrode 124 in electrical communication with first liquid 106. Additionally, or alternatively, electrowetting device 100 comprises a driving electrode 126 disposed on a sidewall of cavity 104 and insulated from first liquid 106 and second liquid 108. Different voltages can be supplied to common electrode 124 and driving electrode 126 (e.g., a voltage differential can be applied between the common electrode and the driving electrode) to change the shape of interface 110 as described herein.

In some embodiments, electrowetting device 100 comprises a conductive layer 128 at least a portion of which is disposed within cavity 104. For example, conductive layer 128 comprises a conductive coating applied to intermediate layer 120 prior to bonding first outer layer 118 and/or second outer layer 122 to the intermediate layer. Conductive layer 128 can comprise a metallic material, a conductive polymer material, another suitable conductive material, or a combination thereof. Additionally, or alternatively, conductive layer 128 can comprise a single layer or a plurality of layers, some or all of which can be conductive. In some embodiments, conductive layer 128 defines common electrode 124 and/or driving electrode 126. For example, conductive layer 128 can be applied to substantially the entire outer surface of intermediate layer 118 prior to bonding first outer layer 118 and/or second outer layer 122 to the intermediate layer. Following application of conductive layer 128 to intermediate layer 118, the conductive layer can be segmented into various conductive elements (e.g., common electrode 124 and/or driving electrode 126 as described herein). In some embodiments, electrowetting device 100 comprises a scribe 130A in conductive layer 128 to isolate (e.g., electrically isolate) common electrode 124 and driving electrode 126 from each other. In some embodiments, scribe 130A comprises a gap in conductive layer 128. For example, scribe 130A is a gap with a width of about 5 μm, about 10 μm, about 15 μm, about 20 μm, about 25 μm, about 30 μm, about 35 μm, about 40 μm, about 45 μm, about 50 μm, or any ranges defined by the listed values.

In some embodiments, electrowetting device 100 comprises an insulating layer 132 disposed within cavity 104. For example, insulating layer 132 comprises an insulating coating applied to intermediate layer 120 prior to bonding first outer layer 118 and/or second outer layer 122 to the intermediate layer. In some embodiments, insulating layer 132 comprises an insulating coating applied to conductive layer 128 and second window 116 after bonding second outer layer 122 to intermediate layer 120 and prior to bonding first outer layer 118 to the intermediate layer. Thus, insulating layer 132 covers at least a portion of conductive layer 128 within cavity 104 and second window 116. In some embodiments, insulating layer 132 can be sufficiently transparent to enable passage of image radiation through second window 116 as described herein. Insulating layer 132 can comprise polytetrafluoroethylene (PTFE), parylene, another suitable polymeric or non-polymeric insulating material, or a combination thereof. Additionally, or alternatively, insulating layer 132 comprises a hydrophobic material. Additionally, or alternatively, insulating layer 132 can comprise a single layer or a plurality of layers, some or all of which can be insulating. In some embodiments, insulating layer 132 covers at least a portion of driving electrode 126 (e.g., the portion of the driving electrode disposed within cavity 104) to insulate first liquid 106 and second liquid 108 from the driving electrode. Additionally, or alternatively, at least a portion of common electrode 124 disposed within cavity 104 is uncovered by insulating layer 132. Thus, common electrode 124 can be in electrical communication with first liquid 106 as described herein. In some embodiments, insulating layer 132 comprises a hydrophobic surface layer of second portion 104B of cavity 104. Such a hydrophobic surface layer can help to maintain second liquid 108 within second portion 104B of cavity 104 (e.g., by attraction between the non-polar second liquid and the hydrophobic material) and/or enable the perimeter of interface 110 to move along the hydrophobic surface layer (e.g., by electrowetting) to change the shape of the interface as described herein.

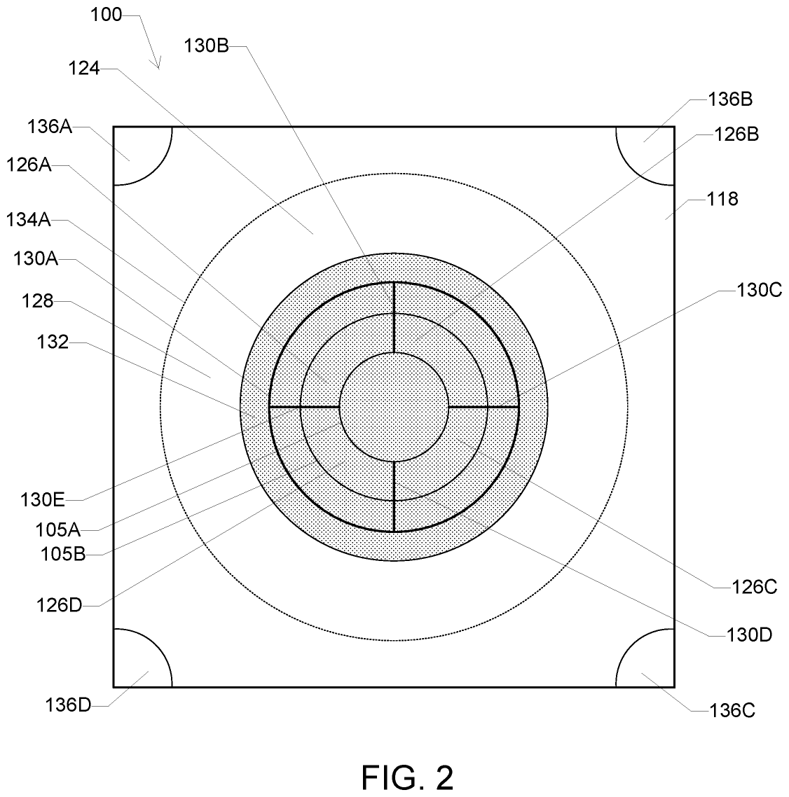

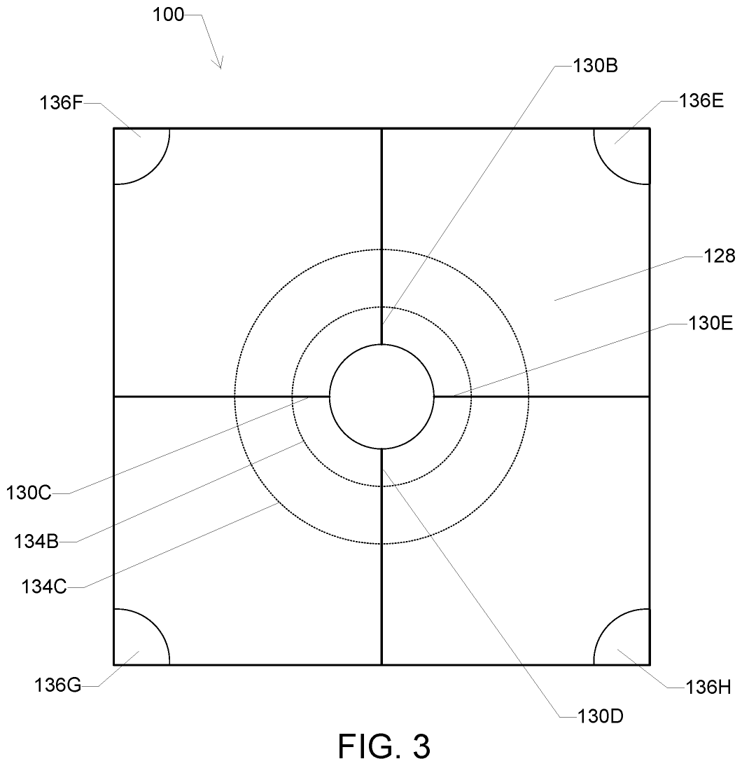

FIG. 2 is a schematic front view of electrowetting device 100 looking through first outer layer 118, and FIG. 3 is a schematic rear view of the electrowetting device looking through second outer layer 122. For clarity in FIGS. 2 and 3, and with some exceptions, bonds generally are shown in dashed lines, scribes generally are shown in heavier lines, and other features generally are shown in lighter lines.

In some embodiments, common electrode 124 is defined between scribe 130A and bond 134A, and a portion of the common electrode is uncovered by insulating layer 132 such that the common electrode can be in electrical communication with first liquid 106 as described herein. In some embodiments, bond 134A is configured such that electrical continuity is maintained between the portion of conductive layer 128 inside the bond (e.g., inside cavity 104) and the portion of the conductive layer outside the bond. In some embodiments, electrowetting device 100 comprises one or more cutouts 136 in first outer layer 118. For example, in the embodiments shown in FIG. 2, electrowetting device 100 comprises a first cutout 136A, a second cutout 136B, a third cutout 136C, and a fourth cutout 136D. In some embodiments, cutouts 136 comprise portions of electrowetting device 100 at which first outer layer 118 is removed to expose conductive layer 128. Thus, cutouts 136 can enable electrical connection to common electrode 124, and the regions of conductive layer 128 exposed at cutouts 136 can serve as contacts to enable electrical connection of electrowetting device 100 to a controller, a driver, or another component of a lens or camera system.

In some embodiments, driving electrode 126 comprises a plurality of driving electrode segments. For example, in the embodiments shown in FIGS. 2 and 3, driving electrode 126 comprises a first driving electrode segment 126A, a second driving electrode segment 126B, a third driving electrode segment 126C, and a fourth driving electrode segment 126D. In some embodiments, the driving electrode segments are distributed substantially uniformly about the sidewall of cavity 104. For example, each driving electrode segment occupies about one quarter, or one quadrant, of the sidewall of second portion 104B of cavity 104. In some embodiments, adjacent driving electrode segments are isolated from each other by a scribe. For example, first driving electrode segment 126A and second driving electrode segment 126B are isolated from each other by a scribe 130B. Additionally, or alternatively, second driving electrode segment 126B and third driving electrode segment 126C are isolated from each other by a scribe 130C. Additionally, or alternatively, third driving electrode segment 126C and fourth driving electrode segment 126D are isolated from each other by a scribe 130D. Additionally, or alternatively, fourth driving electrode segment 126D and first driving electrode segment 126A are isolated from each other by a scribe 130E. The various scribes 130 can be configured as described herein in reference to scribe 130A. In some embodiments, the scribes between the various electrode segments extend beyond cavity 104 and onto the back side of electrowetting device 100 as shown in FIG. 3. Such a configuration can ensure electrical isolation of the adjacent driving electrode segments from each other. Additionally, or alternatively, such a configuration can enable each driving electrode segment to have a corresponding contact for electrical connection as described herein.

Although driving electrode 126 is described herein in reference to FIGS. 1-3 as being divided into four driving electrode segments, other embodiments are included in this disclosure. In some other embodiments, the driving electrode comprises a single electrode (e.g., an undivided driving electrode). In some other embodiments, the driving electrode is divided into two, three, five, six, seven, eight, or more driving electrode segments.

In some embodiments, bond 134B and/or bond 134C are configured such that electrical continuity is maintained between the portion of conductive layer 128 inside the respective bond and the portion of the conductive layer outside the respective bond. In some embodiments, electrowetting device 100 comprises one or more cutouts 136 in second outer layer 122. For example, in the embodiments shown in FIG. 3, electrowetting device 100 comprises a fifth cutout 136E, a sixth cutout 136F, a seventh cutout 136G, and an eighth cutout 136H. In some embodiments, cutouts 136 comprise portions of electrowetting device 100 at which second outer layer 122 is removed to expose conductive layer 128. Thus, cutouts 136 can enable electrical connection to driving electrode 126, and the regions of conductive layer 128 exposed at cutouts 136 can serve as contacts to enable electrical connection of electrowetting device 100 to a controller, a driver, or another component of a lens or camera system.

Different driving voltages can be supplied to different driving electrode segments to tilt the interface of the electrowetting device (e.g., for OIS functionality). Additionally, or alternatively, the same driving voltage can be supplied to each driving electrode segment to maintain the interface of the electrowetting device in a substantially spherical orientation about the optical axis (e.g., for autofocus functionality).

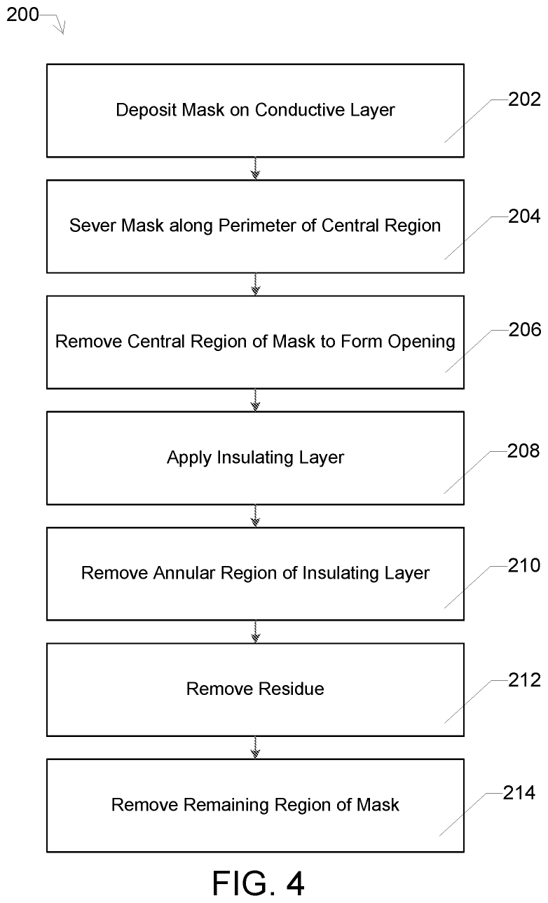

FIG. 4 is a flowchart illustrating some embodiments of a method 200 for forming a patterned insulating layer on a conductive layer. Method 200 can be used to manufacture a variety of devices, including for example, electrowetting devices such as electrowetting device 100 described herein. In some embodiments, method 200 comprises depositing a mask on a conductive layer at step 202.

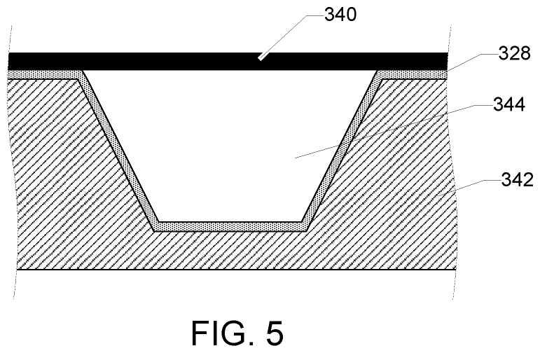

FIG. 5 is a schematic cross-sectional view of some embodiments of a mask 340 disposed on a conductive layer 328. In some embodiments, mask 340 comprises a polymeric tape that is adhered to conductive layer 328. For example, mask 340 comprises a polymeric carrier and an adhesive disposed on a surface of the polymeric carrier to adhere the polymeric carrier to conductive layer 328. In some embodiments, mask 340 is an unstructured mask that can be patterned as described herein. Mask 340 can comprise, for example, a polyimide tape (e.g., Kapton tape available from E. I. du Pont de Nemours and Company (Wilmington, Del., USA)), polyvinyl chloride (PVC) tape, polyolefin tape, polyethylene tape, or another suitable polymeric tape or dicing tape. In some embodiments, mask 340 is not an ultraviolet (UV) releasable tape or a heat releasable tape, which can help to prevent premature release of the tape upon exposure to electromagnetic radiation and/or heat during the processing described herein. Additionally, or alternatively, mask 340 can have low stretch and/or medium tack. In some embodiments, a thickness of the polymeric tape is about 50 μm, about 60 μm, about 70 μm, about 80 μm, about 90 μm, about 100 μm, about 110 μm, about 120 μm, about 130 μm, about 140 μm, about 150 μm, about 160 μm, about 170 μm, about 180 μm, about 190 μm, about 200 μm, or any ranges defined by the listed values.

In some embodiments, conductive layer 328 can be configured as described herein in reference to conductive layer 128. In some embodiments, conductive layer 328 is disposed on a substrate 342. Substrate 342 can be substantially flat (e.g., planar) or non-flat (e.g., non-planar). For example, in some embodiments, substrate 342 comprises a well 344 disposed therein as shown in FIG. 5. For example, substrate 342 can be configured as a portion of body 102 (e.g., intermediate layer 120 and second outer layer 122 with cavity 104 disposed therein) of electrowetting device 100. In some embodiments, mask 340 overlies well 344 such that a portion of the mask at least partially covers an opening of the well. Mask 340 can be patterned to serve as a mask or template for depositing a patterned insulating layer on conductive layer 328 as described herein.

In some embodiments, method 200 comprises severing the mask disposed on the conductive layer along a perimeter of a central region of the mask at step 204 as shown in FIG. 4.

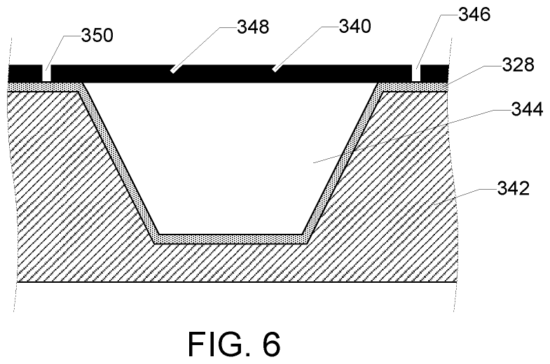

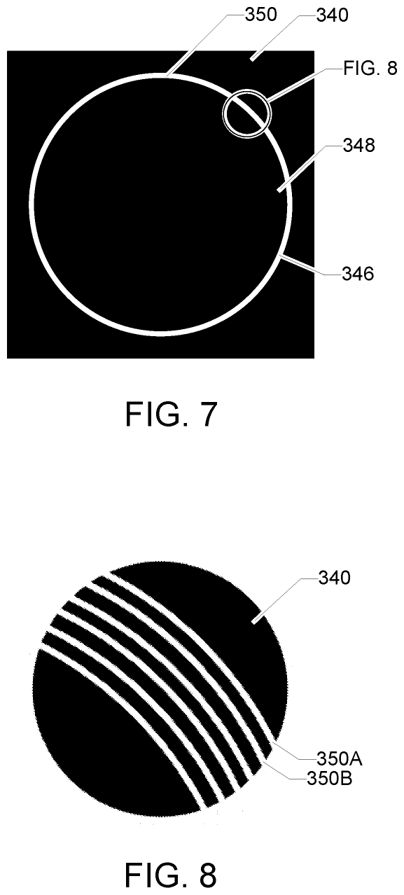

FIGS. 6 and 7 are schematic cross-sectional and top views, respectively, of some embodiments of mask 340 severed along a perimeter 346 of a central region 348 of the mask. In some embodiments, severing mask 340 forms a gap 350 in the mask about perimeter 346 of central region 348. In some embodiments, mask 340 is severed using photochemical ablation. For example, mask 340 can be severed using a laser with a sufficiently high photon energy and sufficiently low wavelength for photochemical ablation of the mask. Table 1 shows the bond energy, in electron volts (eV), of various chemical bonds, and Table 2 shows the photon energy, also in eV, of electromagnetic radiation of various wavelengths.

TABLE 1
Bond Energy of Various Chemical Bonds

| Chemical Bond | Bond Energy (eV) |
|---|---|
| C—C | 3.586 |
| C—H | 4.477 |
| C—Cl | 3.389 |
| C—O | 3.71 |
| C—N | 3.161 |
| Si—O | 4.685 |
| C═C | 6.239 |
| C═O | 8.281 |

TABLE 2
Photon Energy of Electromagnetic
Radiation of Various Wavelengths

| Wavelength (nm) | Photon Energy (eV) |
|---|---|
| 257 | 4.82429 |
| 355 | 3.49251 |
| 532 | 2.33053 |
| 1064 | 1.16527 |

In some embodiments, severing mask 340 comprises exposing the mask to electromagnetic radiation (e.g., by irradiating the mask with a laser) having a sufficiently high photon energy and/or a sufficiently low wavelength to photochemically break some or all of the chemical bonds of the mask material. For example, the electromagnetic radiation can have a photon energy of at least about 3.161 eV, at least about 3.389 eV, at least about 3.586 eV, at least about 3.71 eV, at least about 4.477 eV, or at least about 4.685 eV. Additionally, or alternatively, the electromagnetic radiation can have a wavelength of at most about 393 nm, at most about 366 nm, at most about 346 nm, at most about 335 nm, at most about 277 nm, or at most about 265 nm. In some embodiments, mask 340 can comprise, consist essentially of, or consist of chemical bonds having a bond energy of less than or equal to the photon energy of the electromagnetic radiation. Thus, exposing mask 340 to the electromagnetic radiation can break some of all of the bonds of the mask, thereby severing the mask by photochemical ablation.

In some embodiments, severing mask 340 comprises irradiating the mask with a laser as described herein. Severing mask 340 with a laser having a photon energy and/or wavelength as described herein (e.g., for photchemically ablating the mask) can enable the laser to be operated at relatively low power and/or pulse energy. Such operation of the laser can help to avoid burning mask 340 and/or damaging conductive layer 328 underlying the portion of the mask that is severed. In some embodiments, severing mask 340 comprises irradiating the mask using a pulsed laser with an average power of at most about 75 mW (e.g., from about 25 mW to about 75 mW) and/or a pulse energy of at most about 0.3 μJ, at most about 0.25 μJ, at most about 0.225 μJ, at most about 0.2 μJ, at most about 0.19 μJ, at most about 0.18 μJ, at most about 0.17 μJ, at most about 0.16 μJ, or at most about 0.15 μJ.

A laser with a high photon energy (e.g., a 257 nm deep ultraviolet (UV) laser with a photon energy of 4.82 eV) as described herein can break down weaker chemical bonds at the single photon level. Such a laser with high energy photons can be used for photochemical ablation of polymers (e.g., having bond energies of about 3.39 eV to about 4.69 eV) without damaging non-polymer surrounding materials that have stronger chemical bonds above the photon energy threshold. In contrast, irradiating the mask with a laser with low photon energy (e.g., a 355 nm UV-A laser with a photon energy of 3.48 eV) can cause photothermal ablation because the lower photon energy can be below the chemical bond strength for most of the chemical bonds of the mask. Such photothermal ablation can expose the mask to high temperature, which can burn the adhesive (making it difficult to clean off or remove from the underlying conductive layer), damage the underlying substrate, and/or degrade the quality of the mask. Burning the adhesive and/or damaging the substrate can hinder clean deposition and patterning of the insulating layer.

Although perimeter 346 shown in FIGS. 6 and 7 is circular, other embodiments are included in this disclosure. For example, in some other embodiments, the perimeter is triangular, rectangular, elliptical, or another polygonal or non-polygonal shape. The shape of the perimeter of the central region can correspond to the shape of the well in the substrate as described herein.

In some embodiments, severing mask 340 comprises irradiating the mask with a laser in a spiral pattern about perimeter 346 of central region 348 of the mask. FIG. 8 is a close-up view of a portion of some embodiments of gap 350 shown in FIG. 7. In some embodiments, the spiral pattern of gap 350 comprises a plurality of adjacent passes about perimeter 346. In some of such embodiments, the spiral pattern comprises a pitch, or a spacing between adjacent passes (e.g., a spacing between a first pass 350A and a second pass 350B adjacent the first pass). In some embodiments, the spiral pattern comprises about 10 passes, about 20 passes, about 30 passes, about 40 passes, about 50 passes, about 60 passes, about 70 passes, about 80 passes, about 90 passes, about 100 passes, or any ranges defined by the listed values. Additionally, or alternatively, the spiral pattern comprises a pitch of about 2 μm, about 3 μm, about 4 μm, about 5 μm, about 6 μm, about 7 μm, about 8 μm, about 9 μm, about 10 μm, or any ranges defined by the listed values.

In some embodiments, method 200 comprises removing the central region of the mask to form an opening in the mask at step 206 as shown in FIG. 4 and uncover a central region of the conductive layer corresponding to the opening in the mask, whereby a remaining region of the mask surrounding the opening in the mask covers a corresponding surrounding region of the conductive layer.

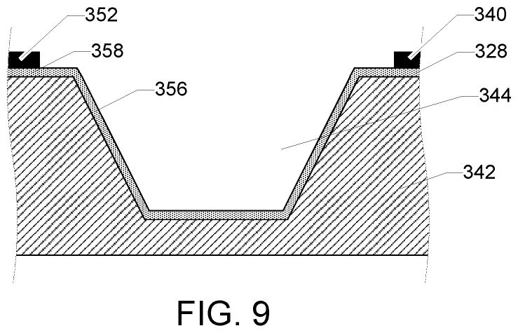

FIG. 9 is a schematic cross-sectional view of some embodiments of mask 340 disposed on conductive layer 328 with central region 348 of the mask removed to form an opening in the mask. In some embodiments, removing central region 348 of mask comprises mechanically removing the central region (e.g., by grasping and lifting the central region) from conductive layer 328. Severing mask 340 about perimeter 346 of central region 348 can enable removal of the central region without disturbing a remaining region 352 of the mask that remains disposed on conductive layer 328 following removal of the central region. Following removal of central region 348, remaining region 352 of mask 340 can comprise a patterned mask that can be used to form the patterned insulating layer on conductive layer 328 as described herein.

In some embodiments, a central region 356 of conductive layer 328 corresponds to (e.g., is covered by) central region 348 of mask 340 such that, following removal of the central region of the mask, the central region of the conductive layer is uncovered by the mask. In some embodiments, following removal of central region 348 of mask 340, a surrounding region 358 of conductive layer 328 remains covered by remaining region 352 of the mask. Thus, remaining region 352 of mask 340 can serve as template or pattern to deposit a coating on central region 356 of conductive layer 328 as described herein.

In some embodiments, severing mask 340 as described herein prior to removing central region 348 of the mask can help to avoid damaging central region 356 of conductive layer 328. For example, severing mask 340 using a laser with relatively low power and/or pulse energy can help to avoid burning the mask and/or damaging conductive layer 328. Additionally, or alternatively, severing mask 340 using a laser as opposed to mechanically cutting the mask (e.g., with a blade) can help to avoid scratching conductive layer 328. In some embodiments, following removal of central region 348 of mask 340 from conductive layer 328, the conductive layer is substantially free of scratches and thermal damage. For example, an edge portion of central region 356 of conductive layer 328 and/or surrounding region 358 of the conductive layer can be substantially free of scratches and thermal damage. For example, conductive layer 328 can be considered substantially free of scratches and thermal damage if the surface roughness of the edge portion of central region 356 (e.g., corresponding to gap 350) is no more than 10% greater than the surface roughness of the remaining portion of the central region (e.g., an interior portion of the central region inboard of gap 350). The surface roughness can be Ra surface roughness determined as described in ISO 25178, Geometric Product Specifications (GPS)—Surface texture.

In some embodiments, method 200 comprises applying an insulating layer to the central region of the conductive layer and the remaining region of the mask at step 208 as shown in FIG. 4.

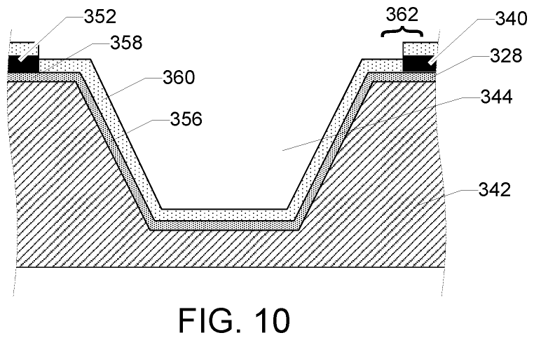

FIG. 10 is a schematic cross-sectional view of some embodiments of an insulating layer 360 disposed on conductive layer 328. In some embodiments, insulating layer 360 is deposited on both central region 356 of conductive layer 328 and remaining region 352 of mask 340. Thus, mask 340 shields surrounding region 358 of conductive layer 328 such that insulating layer 360 is not disposed on the surrounding region of the conductive layer. Insulating layer 360 can be deposited using vapor deposition (e.g., chemical vapor deposition or chemical vapor deposition), spray coating, spin coating, dip coating, or another suitable deposition process.

In some embodiments, method 200 comprises removing an annular region of the insulating layer overlying the perimeter of the opening in the mask at step 210 as shown in FIG. 4.

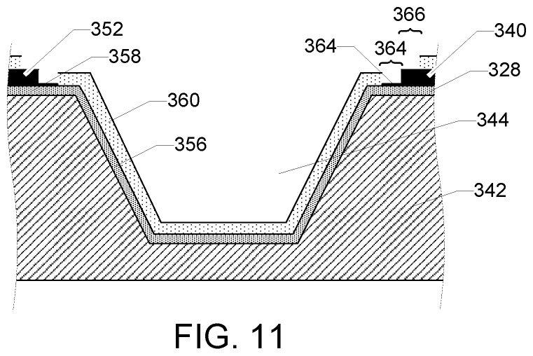

FIG. 11 is a schematic cross-sectional view of some embodiments of insulating layer 360 disposed on conductive layer 328 with an annular region 362 (shown in FIG. 10) of the insulating layer removed. In some embodiments, annular region 362 overlies perimeter 346 of central region 348 of mask 340. For example, annular region 362 overlies an edge of the opening in mask 340. In some embodiments, prior to removal, an inner portion of annular region 362 is disposed on central region 356 of conductive layer 328, and an outer portion of the annular region is disposed on mask 340. Thus, following removal of annular region 362, an annular portion 364 of central region 356 of conductive layer 328 is uncovered by each of mask 340 and insulating layer 360, and an annular portion 366 of the mask is uncovered by the insulating layer. In some embodiments, annular region 362 spans from inside to outside of mask 340. Removing such annular region 362 can enable a high quality patterned insulating layer edge on the inside and/or create a clean break from the portion of insulating layer 360 disposed on top of mask 340 to facilitate removal of the mask as described herein without damage to the insulating layer.

Removing annular region 362 of insulating layer 360 can enable removal of mask 340 from conductive layer 328 as described herein without disturbing the edge of the patterned insulating layer. For example, annular region 362 can serve as a break or gap between a portion of insulating layer 360 disposed on conductive layer 328 and a portion of the insulating layer disposed on remaining region 352 of mask 340 such that the remaining region of the mask can be lifted from the conductive layer without pulling on or potentially tearing the edge of the patterned insulating layer. Thus, the patterned insulating layer can be substantially free of flaps and/or stringers as described herein.

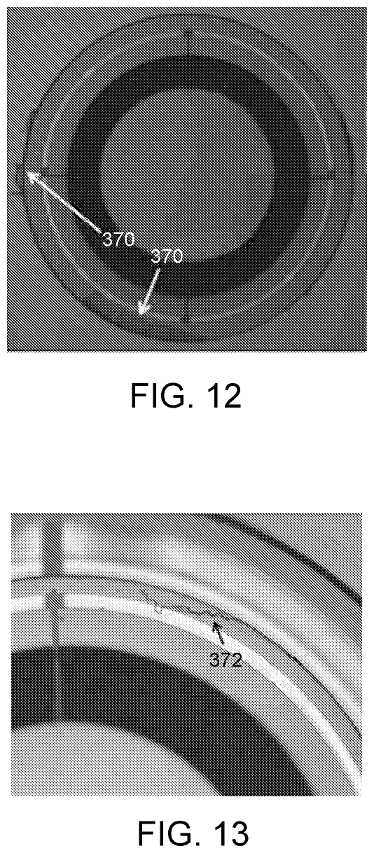

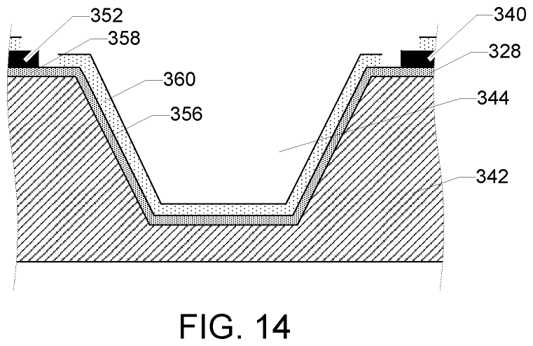

FIGS. 12 and 13 are photographs of patterned insulating layers formed on conductive layers without removing annular regions of the insulating layers prior to removing the masks as described herein. The insulating layer shown in FIG. 12 has flaps 370, which can be relatively wide and/or short extensions of the material of the insulating layer that can fold over to contact the bulk of the insulating layer. The insulating layer shown in FIG. 13 has a stringer 372, which can be relatively long and/or narrow strings of the material of the insulating layer that can extend away from the insulating layer and float in the liquids. In some embodiments, the patterned insulating layer can be considered to be free of stringers if it is free of stringers that are sufficiently large (e.g., long) to extend into a cylindrical extension of cavity 104 (e.g., wide end 105B of the cavity). Flaps and/or stringers on the insulating layer can result from portions of the insulating layer adhered to the vertical section of the mask. When the mask is lifted, the vertical portion of the insulating layer can fall down. The portion of the insulating layer that falls can be fused back onto the patterned insulating layer during a following clean-up step (e.g., removal of the residue) as described herein. By cutting the insulating layer from inside to outside of this vertical section (e.g., removing the annular region), the vertical portion of the insulating layer that could form a flap and/or a stringer can be removed, and the flap and/or stringer defects can be avoided.

In some embodiments, annular region 362 of insulating layer 360 can be removed by laser ablation, mechanical cutting, or another suitable removal process. For example, annular region 362 of insulating layer 360 is removed by photothermal ablation. In some embodiments, removing annular region 362 of insulating layer 360 comprises exposing the annular region of the insulating layer to electromagnetic radiation (e.g., using a laser) with a photon energy of at most about 3.586 eV, at most about 3.389 eV, or at most about 3.161 eV. Additionally, or alternatively, removing annular region 362 of insulating layer 360 comprises exposing the annular region of the insulating layer to electromagnetic radiation with a wavelength of at least about 345 nm, at least about 365 nm, or at least about 392 nm. Such photon energy and/or wavelengths can help to avoid damaging underlying layers (e.g., conductive layer 358), which could disrupt adhesion of insulating layer 360. In some embodiments, during the removing annular region 362 of insulating layer 360 by photothermal ablation, annular portion 366 of mask 340 can be partially or entirely removed as well.

In some embodiments, after removing annular region 362 of insulating layer 360, residue 364 from at least one of mask 340 or the insulating layer is disposed on the annular region of conductive layer 328 as shown in FIG. 11. For example, residue 364 can comprise a portion of the adhesive of mask 340, a portion of the carrier of the mask, and/or a portion of insulating layer 360.

In some embodiments, method 200 comprises removing residue from an annular region of the conductive layer corresponding to the annular region of the insulating layer at step 212 as shown in FIG. 4. In some embodiments, removing the residue comprises irradiating the annular region of the conductive layer with a laser to remove the residue.

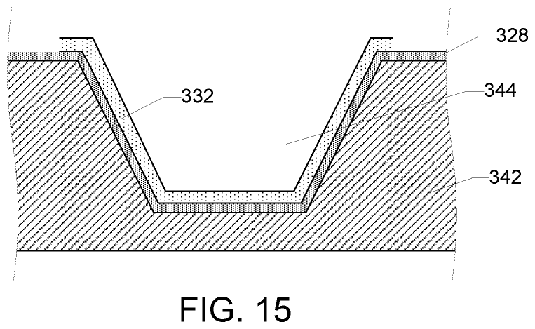

FIG. 14 is a schematic cross-sectional view of some embodiments of insulating layer 360 disposed on conductive layer 328 with residue 364 removed. In some embodiments, residue 364 can be removed by laser ablation, mechanical removal, or another suitable removal process. In some embodiments, removing residue 364 comprises exposing the residue to electromagnetic radiation (e.g., using a laser) with a photon energy of at most about 3.586 eV, at most about 3.389 eV, or at most about 3.161 eV. Additionally, or alternatively, removing residue 364 comprises exposing the residue to electromagnetic radiation with a wavelength of at least about 345 nm, at least about 365 nm, or at least about 392 nm. Annular region 362 of insulating layer 360 and residue 364 can be removed using the same or different processes.

In some embodiments, removing annular region 362 and/or removing residue 364 are performed by irradiating the annular region, annular portion 364, and/or annular portion 366 with a pulsed laser to ablate (e.g., by photothermal ablation) of insulating layer 360 and/or the residue, which can enable cleaner removal of remaining region 352 of mask 340 as described herein. For example, a laser with a moderate photon energy (e.g., a 355 nm laser with a photon energy of 3.49 eV) can break some weaker chemical bonds, while higher peak power pulses can create relatively high local temperature to ablate portions of residual adhesive materials of mask 340, insulating layer 360, and/or underlying conductive layer 356.

In some embodiments, method 200 comprises removing the remaining region of the mask from the conductive layer at step 214 as shown in FIG. 4 to remove an excess portion of the insulating layer disposed on the remaining region of the mask. Following the removing the remaining region of the mask, a remaining portion of the insulating layer corresponding to the opening in the mask can define the patterned insulating layer disposed on the central region of the conductive layer. Additionally, or alternatively, the surrounding region of the conductive layer can be uncovered by the patterned insulating layer.

FIG. 15 is a schematic cross-sectional view of some embodiments of a patterned insulating layer 332 disposed on conductive layer 328 following removal of remaining region 352 of mask 340 from the conductive layer. In some embodiments, remaining region 352 of mask 340 can be removed from conducting layer 328 by mechanically lifting the remaining region of the mask from the conductive layer. Removal of remaining region 352 of mask 340 can result in removal of the portion of insulating layer 360 (e.g., the excess portion of the insulating layer) disposed on the remaining region of the mask, leaving patterned insulating layer 332 disposed on conductive layer 328. The methods described herein for forming patterned insulating layer 332 can enable the patterned insulating layer to have improved edge quality. For example, in some embodiments, patterned insulating layer 332 can be substantially free of flaps and stringers. Such improved edge quality can enable improved performance and/or reliability (e.g., in devices such as, for example, electrowetting device 100 as described herein). In some embodiments, patterned insulating layer 332 can be configured as described herein in reference to insulating layer 132.

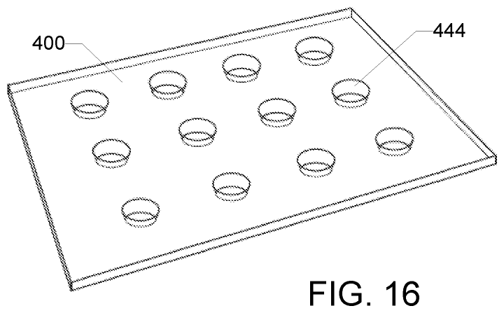

In some embodiments, method 200 can be used as part of a wafer manufacturing process. FIG. 16 is a perspective view of some embodiments of a substrate wafer 400 comprising a plurality of wells 444 formed therein. The substrate wafer can be coated with a conductive layer as described herein. The steps described herein in reference to method 200 can be performed on wafer 400 to manufacture a plurality of patterned insulating layers on the conductive layer. For example, a mask can be applied to the substrate wafer. In some embodiments, the mask can overlie the plurality of wells. The mask can be severed along the perimeter of each of a plurality of central regions of the mask corresponding to the plurality of wells. The plurality of central regions of the mask can be removed to form a plurality of openings in the mask corresponding to the plurality of wells. The insulating layer can be applied to a plurality of central regions of the conductive layer corresponding to the plurality of openings in the mask and the remaining region of the mask. A plurality of annular regions of the insulating layer corresponding to the plurality of wells can be removed. The remaining region of the mask can be removed from the conductive layer, leaving the patterned insulating layer thereon. Substrate wafer 400 with the patterned insulating layer thereon can be diced or singulated to separate individual devices each having one or more wells therein.

Although substrate wafer 400 shown in FIG. 16 is rectangular, other embodiments are included in this disclosure. For example, in some other embodiments, the substrate wafer is triangular, circular (with or without a reference flat), elliptical, or another polygonal or non-polygonal shape. Although substrate wafer 400 shown in FIG. 16 comprises twelve wells, other embodiments are included in this disclosure. For example, in some other embodiments, the substrate wafer comprises two, three, four, five, or more wells.

In some embodiments, method 200 can be used to manufacture an electrowetting device such as, for example, electrowetting device 100 described herein. For example, substrate 342 can form a portion of body 102 of electrowetting device 100, conductive layer 328 can form conductive layer 128 of the electrowetting device, and/or patterned insulating layer 332 can form insulating layer 132 of the electrowetting device. In other embodiments, method 200 can be used to manufacture other devices comprising a patterned insulating layer disposed on a conductive layer (e.g., microelectromechanical (MEMS) devices for various end applications).

### Example

Various embodiments will be further clarified by the following example.

A 100 μm thick unstructured tape mask was applied over the entirety of a metallized wafer with a plurality of wells formed therein. The tape mask was Adwill P series, non-UV type BG tape commercially available from LINTEC Corporation (Tokyo, Japan). The metal on the metallized wafer was a multi-layer metal stack including a Cr layer and a CrOₓN_{y} layer. The outside edges of the tape mask extending beyond the edges of the wafer were cut away. A circular perimeter was cut in the tape mask about each of the plurality of wells using a 257 nm UV laser with settings of 50 mW average power, 500 kHz pulse repetition rate, and 0.10 μJ pulse energy with a spot size of approximately 5 to 20 μm. The tape mask was cut with the laser in a spiral pattern having 30 to 40 passes and a 3 μm pitch. The ratio of the spot size of the laser to the thickness of the mask can be about 3 to about 20. The tape mask was ablated in the spiral pattern around the outside of the well so that the ablated tape did not lift off the wafer.

The laser produced 257 nm photons with a 4.82 eV photon energy. Thus, without wishing to be bound by any theory, it is believed that each of these high energy photons had the ability to break down weaker chemical bonds of the polymer tape mask, and also that the low pulse energy and low average power maintained the temperature during the cutting relatively low to avoid burning the tape mask.

The central region of the tape mask overlying each of the plurality of wells was removed. A conformal parylene coating was applied to the wafer.

The tape mask-parylene interface (e.g., an annular region of the parylene coating at the interface with the tape mask) was ablated using a 355 nm UV-A laser with a 10 μm spot size and a pulse energy of 0.36 uJ. The laser was first used to ablate the outside area of parylene that overlapped with the tape mask. The laser cut from just inside the tape moving across to outside the tape, creating a ring of ablated parylene and tape mask. This laser trim step resulted in some damage to the tape mask adhesive where the laser irradiated the tape mask. The laser then was used to clean up the residue that formed during the laser trim step. The laser clean-up step also can remove defects (e.g., air bubbles that formed with incomplete tape coverage). Without wishing to be bound by any theory, it is believed that the lower 3.49 eV energy of the laser resulted in photothermal ablation to remove the parylene spanning inside to outside of the tape mask boundary.

The remaining tape mask was peeled off to complete the parylene patterning procedure. The surrounding region of the metal layer was substantially free of scratches and thermal damage. Upon visual inspection, the patterned parylene was free of flaps and stringers.

It will be apparent to those skilled in the art that various modifications and variations can be made without departing from the spirit or scope of the claimed subject matter. Accordingly, the claimed subject matter is not to be restricted except in light of the attached claims and their equivalents.

1. A method for forming a patterned insulating layer on a conductive layer, the method comprising:
severing a mask disposed on the conductive layer using photochemical ablation along a perimeter of a central region of the mask;
removing the central region of the mask to form an opening in the mask and uncover a central region of the conductive layer corresponding to the opening in the mask, whereby a remaining region of the mask surrounding the opening in the mask covers a corresponding surrounding region of the conductive layer;
applying an insulating layer to the central region of the conductive layer and the remaining region of the mask;
removing the remaining region of the mask from the conductive layer to remove an excess portion of the insulating layer disposed on the remaining region of the mask, whereby a remaining portion of the insulating layer corresponding to the opening in the mask defines the patterned insulating layer disposed on the central region of the conductive layer, and the surrounding region of the conductive layer is uncovered by the patterned insulating layer.

2. The method of claim 1, wherein the severing the mask comprises exposing the mask to electromagnetic radiation with a photon energy of at least about 3.586 eV along the perimeter of the central region of the mask.

3. The method of claim 1, wherein the severing the mask comprises exposing the mask to electromagnetic radiation with a wavelength of at most about 346 nm along the perimeter of the central region of the mask.

4. The method of claim 1, wherein the severing the mask comprises irradiating the mask with a laser in a spiral pattern about the perimeter of the central region of the mask.

5. The method of claim 4, wherein the spiral pattern comprises about 30 passes to about 40 passes and a pitch of about 2 μm to about 5 μm.

6. The method of claim 1, wherein the severing the mask comprises irradiating the mask with a pulsed laser with an average power of at most about 75 mW and a pulse energy of at most about 0.3 μJ.

7. The method of claim 1, wherein the severing the mask comprises irradiating the mask with a pulsed laser with an average power of about 25 mW to about 75 mW, a pulse repetition rate of about 250 kHz to about 750 kHz, and a pulse energy of about 0.05 μJ to about 0.15 μJ.

8. The method of claim 1, wherein the severing the mask comprises irradiating the mask with a laser with a spot size of about 5 μm to about 20 μm.

9. The method of claim 1, wherein:
the severing the mask comprises irradiating the mask with a laser; and
a ratio of a spot size of the laser to a thickness of the mask is about 3 to about 20.

10. The method of claim 1, wherein the severing the mask comprises irradiating the mask with a laser without burning the mask.

11. The method of claim 1, wherein the mask comprises a polymeric tape that is adhered to the conductive layer.

12. The method of claim 11, wherein a thickness of the polymeric tape is about 50 μm to about 200 μm.

13. The method of claim 1, wherein:
the conductive layer is disposed on a substrate comprising a well formed therein, and the conductive layer is disposed at least partially within the well;
prior to the removing the central region of the mask, the perimeter of the central region of the mask circumscribes the well such that the central region of the mask overlies the well; and
after the removing the central region of the mask, the opening in the mask overlies the well.

14. The method of claim 13, wherein:
the substrate comprises a wafer;
the well comprises a plurality of wells;
the severing the mask comprises severing the mask along the perimeter of each of a plurality of central regions of the mask corresponding to the plurality of wells;
the removing the central region of the mask comprises removing the plurality of central regions of the mask to form a plurality of openings in the mask corresponding to the plurality of wells; and
the applying the insulating layer comprises applying the insulating layer to a plurality of central regions of the conductive layer corresponding to the plurality of openings in the mask and the remaining region of the mask.

15. A method for forming a patterned insulating layer on a conductive layer, the method comprising:
applying a mask to the conductive layer disposed on a wafer comprising a plurality of wells;
severing the mask with a pulsed laser with an average power of at most about 75 mW and a pulse energy of at most about 0.3 μJ along a perimeter of each of a plurality of central regions of the mask, each of the plurality of central regions overlying a corresponding one of the plurality of wells;
removing each of the plurality of central regions of the mask to form a plurality of openings in the mask and uncover a plurality of central regions of the conductive layer each disposed at least partially in a corresponding one of the plurality of wells, whereby a remaining region of the mask surrounding the plurality of openings in the mask covers a corresponding surrounding region of the conductive layer disposed outside the plurality of wells;
applying an insulating layer to each of the plurality of central regions of the conductive layer and the remaining region of the mask; and
removing the remaining region of the mask from the conductive layer to remove an excess portion of the insulating layer disposed on the remaining region of the mask, whereby a remaining portion of the insulating layer corresponding to the plurality of openings in the mask defines the patterned insulating layer disposed at least partially within the plurality of wells, and the surrounding region of the conductive layer is uncovered by the patterned insulating layer.

16. The method of claim 15, wherein the surrounding region of the conductive layer is substantially free of scratches and thermal damage.

17. The method of claim 15, wherein the pulsed laser emits electromagnetic radiation with a photon energy of at least about 3.586 eV.

18. The method of claim 1, wherein the pulsed laser emits electromagnetic radiation with a wavelength of at most about 346 nm.

19. An electrowetting device comprising:
a first window, a second window, and a cavity disposed between the first window and the second window;
a first liquid and a second liquid disposed within the cavity;
a liquid interface between the first liquid and the second liquid;
a common electrode in electrical communication with the first liquid;
a driving electrode disposed on a sidewall of the cavity; and
an insulating layer disposed within the cavity to insulate the driving electrode from the first liquid and the second liquid;
wherein an exposed portion of the common electrode disposed within the cavity is substantially free of scratches and thermal damage.

20. The electrowetting device of claim 19, comprising:
an intermediate layer; and
a conductive layer disposed on the intermediate layer, segmented portions of the conductive layer defining the common electrode and the driving electrode.

21-24. (canceled)
